(19) United States
(12) Patent Application Publication
(10) Pub. No.: US 2007/0115033 A1
(43) Pub. Date: May 24, 2007

(54) CLASS-AB OUTPUT CIRCUIT

(75) Inventor: Takeshi KUWANO, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/556,891

(22) Filed: Nov. 6, 2006

(30) Foreign Application Priority Data
Nov. 18, 2005 (JP) 2005-333950

(51) Int. Cl. H03B 1/00

(52) U.S. Cl. 327/108

(57) ABSTRACT

An output circuit includes: a current source transistor connected between a high-potential-side power supply and an output terminal; a current sinking transistor connected between a low-potential-side power supply and the output terminal; a third transistor constituting a current mirror circuit together with the current source transistor; a fourth transistor connected with the third transistor to control a driving current of the current source transistor; and a fifth transistor supplying a current corresponding to a base potential of the current sinking transistor to the fourth transistor.

### BACKGROUND OF THE INVENTION

1. Field of the Invention

The present invention relates to an amplifier for a class-AB operation.

2. Description of Related Art

In recent years, a semiconductor device used in an electronic device has proceeded toward reduction in power supply voltage and power consumption. With this trend, an amplifier circuit incorporated in the semiconductor device has also proceeded toward reduction in power supply voltage and power consumption. Regarding a performance of the amplifier circuit, there is an increasing demand to expand an output voltage range and improve power efficiency despite of a low power supply voltage.

As such circuit configuration that expands an output voltage range, an amplifier performing a rail-to-rail operation is adopted in some cases. FIG. 4 is a circuit diagram showing the configuration of an output circuit using the amplifier performing a rail-to-rail operation. An output circuit 3 of FIG. 4 includes two PNP transistors 301 and 302, an NPN transistor 303, a resistor 304, and a constant current circuit 305.

As shown in FIG. 4, the input terminal 308 is connected with a base terminal of the transistor 303. An input signal IN applied to the input terminal 308 drives the transistor 303. A collector terminal of the transistor 303 is connected with a collector terminal of the transistor 302. Further, the collector terminal of the transistor 303 is connected with an output terminal 309 of the output circuit 3. In addition, the emitter terminal of the transistor 303 is grounded (GND). The transistor 303 is a current sinking transistor controlling an amount of current sunk from the output terminal 309.

On the other hand, an emitter terminal of the transistor 302 is connected with a power supply 306. Further, a base terminal of the transistor 302 is connected with a base terminal of the transistor 301. The transistor 302 is a current source transistor controlling an amount of current supplied from the output terminal 309 to the outside. Further, an emitter terminal of the transistor 301 is connected with a power supply 307 via the resistor 304. Further, a base terminal of the transistor 301 is connected with a collector terminal. The collector terminal of the transistor 301 is grounded through the constant current circuit 305. The transistor 301 and the transistor 302 constitute a current mirror circuit 306.

An output unit of the output circuit 3 is configured by a pure complementary circuit where the transistor 302 as the current source transistor is a PNP transistor and the transistor 303 as the current sinking transistor is an NPN transistor. Thus, it is possible to increase the maximum value of the output voltage Vout up to a power supply Vcc level and decrease the minimum value thereof down to a GND level.

In the output circuit 3, a current I1 that is determined by the constant current circuit 305 is supplied to the transistor 301 of the current mirror circuit 306, and current I2 that flow a collector of the transistor 302 is output according to a predetermined mirror ratio. The current I2 is held constant regardless of a level of the input signal IN. A current I4 is supplied to an output load; the current I4 corresponds to a difference between the current I2 and a current I3 flowing through a collector of the transistor 303, which is controlled by the input signal IN. Then, an output voltage Vout is output. That is, since an idling current (I2) kept constant flows in the output circuit regardless of the level of the input signal IN, this circuit is disadvantageous in that a power efficiency is low when no signal is input.

As a circuit that can overcome the above problem, there has been known a class-B push-pull output circuit. FIG. 5 is a circuit diagram showing the configuration of the class-B push-pull output circuit. A class-B push-pull output circuit 4 of FIG. 5 includes NPN transistors 401 and 403, aPNP transistor 402, two diodes 404 and 405, and a constant current circuit 406.

As shown in FIG. 5, an input terminal 408 is connected with a base terminal of the transistor 403. An input signal IN applied to the input terminal 408 drives the transistor 403. A collector terminal of the transistor 403 is connected with a cathode of the diode 405 and a base of the transistor 402. An emitter terminal of the transistor 403 is grounded. An anode of the diode 405 is connected with a cathode of the diode 404. An anode of the diode 404 is connected with the other end of the constant current circuit 406, one end of which is connected with the power supply 407, and with the base of the transistor 401. The transistor 401 and the transistor 402 are commonly connected with the output terminal 409, and a collector of the transistor 401 is connected with the power supply 407. The transistor 402 is grounded (GND).

In the class-B push-pull output circuit 4, a current I1 supplied from the constant current circuit 406 flows through the diodes 404 and 405. This causes voltage drop, and a bias voltage is applied to the base terminals of the transistor 401 and the transistor 402. If a signal is input to the input terminal 408, an amount of the current I2 flowing the collector of the transistor 403 changes. Then, current I3a that corresponds a difference between the currents I1 and I2 drives the transistor 401. And, current I3b that corresponds a difference between the currents I1 and I2 drives the transistor 402. After that, the output voltage Vout is changed.

If no signal is input to the input terminal 408, the transistor 403 is turned OFF. At this time, the current I2 does not flow. In the class-B push-pull output circuit 4, the transistors 401 and 402 operate only when a signal is input. Hence, its power efficiency is higher than the output circuit 3 of FIG. 4.

However, in the configuration of the class-B push-pull output circuit 4, there are voltage differences Vbe1 and Vbe2 on the GND side and the power supply side as viewed from the output terminal 409, so an output voltage range is narrow. This results in a problem that sufficient output voltage can not be gained in case that a power supply voltage is low.

To solve the aforementioned problems, the following publications are disclosed. According to a technique disclosed in Japanese Patent Translation Publication No. 11-507773, a base potential of a current sinking transistor is controlled by use of a control transistor transmitting an input signal. Further, a current source transistor is controlled through a transistor. The source side transistor and the current sinking transistor are turned ON/OFF in response to the input signal, making it possible to save current consumption and power consumption.

According to a technique disclosed in Japanese Unexamined Patent Publication No. 2000-77955, a base potential of a current sinking transistor is controlled by use of a control transistor transmitting an input signal. Further, a current source transistor is controlled by use of a mirror transistor of the current sinking transistor. The source side transistor and the current sinking transistor are turned ON/OFF in response to the input signal, making it possible to save current consumption and power consumption.

According to a technique disclosed in Japanese Unexamined Patent Publication No. 2003-69346, abase potential of a current sinking transistor is controlled by use of a control transistor transmitting an input signal. Further, a current source transistor is controlled through an idling current control unit. The source side transistor and the current sinking transistor are turned ON/OFF in response to the input of a signal, making it possible to save current consumption and power consumption.

In the configuration disclosed in Japanese Patent Translation Publication No. 11-507773, however, if a potential of the control transistor increases, a gain transistor is turned OFF, and no current flows through the current source transistor, so output impedance becomes extraordinarily high. To adjust the impedance, a current should be continuously supplied from a constant current source. As a result, a current is consumed more than necessary.

Further, in the configuration disclosed in Japanese Unexamined Patent Publication No. 2003-69346, the control of the idling current control unit is limited by a constant current source provided in the idling current control unit. To be specific, if the constant current source is set small, an output current of the current source transistor reduces, making it difficult to increase an input impedance of the current sinking transistor. Therefore, the constant current source can not be set small, and an idling current appears more than necessary. Further, it is necessary to insert an emitter follower circuit to an input signal path for increasing the input impedance.

### SUMMARY OF THE INVENTION

An output circuit according to an aspect of the present invention comprises: a first transistor connected between a high-potential-side power supply and an output terminal; a second transistor connected between a low-potential-side power supply and the output terminal; a third transistor constituting a current mirror circuit together with the first transistor; a fourth transistor connected with the third transistor and controls a drive current of the first transistor; a fifth transistor supplying a current corresponding to a base potential of the second transistor to the fourth transistor.

An output circuit according to an aspect of the present invention comprises: a first transistor having a first terminal connected to a high-potential-side power supply and having a second terminal connected to an output terminal; a second transistor having a first terminal connected to a low-potential-side power supply and having a second terminal connected to the output terminal and having a base terminal connected to an input terminal; a fourth transistor having a second terminal connected to a base terminal of the first transistor; a fifth transistor having a first terminal connected to a first terminal of the fourth transistor and having a base terminal connected to the input terminal.

The fifth transistor synchronous with the second transistor (current sinking transistor) controls the first transistor (current source transistor). Only when a signal is input, the first transistor and the second transistor are driven. Accordingly, current consumption is reduced to save power consumption.

### BRIEF DESCRIPTION OF THE DRAWINGS

The above and other objects, advantages and features of the present invention will be more apparent from the following description taken in conjunction with the accompanying drawings, in which:

FIG. 1 is a circuit diagram showing the configuration of a class-AB output circuit according to an embodiment of the present invention;

FIG. 2 is a circuit diagram showing the simplified configuration of the class-AB output circuit according to the embodiment of the present invention;

FIG. 3 is a circuit diagram showing another mode of the embodiment of the present invention;

FIG. 4 is a circuit diagram showing the configuration of a conventional output circuit; and

FIG. 5 is a circuit diagram showing the configuration of a class-B push-pull output circuit.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

Hereinafter, an embodiment of the present invention is described with reference to the accompanying drawings. In the following description, repetitive explanation is omitted.

This embodiment is described in detail with reference to the accompanying drawings. FIG. 1 is a circuit diagram showing the configuration of a class-AB output circuit 1 of this embodiment. The class-AB output circuit 1 includes four NPN transistors 101, 103, 104, and 106, four PNP transistors 102, 105, 107, and 108, and a constant current circuit 109.

As shown in FIG. 1, an input terminal 113 is connected to a base terminal of the transistor 106. An input signal IN applied to the input terminal 113 drives the transistor 106. Further, the input terminal 113 is also connected to a base terminal of the transistor 105. Thus, the input signal IN drives the transistor 105 as well. A collector terminal of the transistor 106 and a collector terminal of the transistor 108 are connected with an output terminal 114. An emitter terminal of the transistor 106 is grounded (GND). The transistor 106 is a current sinking transistor controlling an amount of current sunk from the output terminal 114.

An emitter terminal of the transistor 108 is connected to a power supply 112. A base terminal of the transistor 108 is connected to a base terminal of the transistor 107. The transistor 108 is a current source transistor controlling an amount of current supplied form the output terminal 114 to the outside. An emitter terminal of the transistor 107 is connected to a power supply 112. A base terminal of the transistor 107 is connected to a collector terminal and to a collector terminal of the transistor 104. The transistor 107 and the transistor 108 constitute a current mirror circuit 110.

On the other hand, an emitter terminal of the transistor 105 is connected with an emitter terminal of the transistor 104. A collector terminal of the transistor 105 is grounded (GND). A base terminal of the transistor 104 is connected with a base terminal of the transistor 101. A base terminal of the transistor 101 is connected with a collector terminal of the transistor 101. An emitter terminal of the transistor 101 is connected with an emitter terminal of the transistor 102. A collector terminal of the transistor 102 is connected with a base terminal of the transistor 102 and a base terminal of the transistor 103. Further, a collector terminal of the transistor 102 is connected with a collector terminal of the transistor 103. An emitter terminal of the transistor 103 is grounded (GND). The transistors 101, 102, 103, 104, and 105 constitute the output control circuit 111.

A collector terminal of the transistor 101 is connected to the power supply 112 via the constant current circuit 109. A collector terminal of the transistor 104 is connected with a collector terminal of the transistor 107. In this way, the class-AB output circuit 1 of this embodiment is configured.

Referring next to FIG. 1, a power efficiency and an output voltage range of the class-AB output circuit 1 of this embodiment are described. First, a base voltage (hereinafter referred to as “point-P voltage”) of the transistors 101 and 104 is considered, and a power efficiency of this embodiment is discussed. A potential of the point P is expressed by the following relational expression (1):

$$\begin{matrix}Point - P voltage = Vbe 1 + Vbe 2 + Vbe 3 \\ = Vbe 4 + Vbe 5 + Vbe 6\end{matrix} \qquad ( 1 )$$

As shown in FIG. 1, a current I1 determined by the constant current circuit 109 flows the transistors 101, 102, and 103. Accordingly, Vbe of the transistors 101, 102, and 103 is fixed. On the other hand, a current I2 that is controlled by a voltage of an input signal IN flows the transistors 104 and 105. Due to the current I2, Vbe4 and Vbe5 fluctuate. Likewise, a current I4 that is controlled by a voltage of the input signal IN flows the transistor 106 as a current sinking transistor. Due to the current I4, Vbe6 fluctuates. That is, an operating point of the transistor 106 varies depending on the input signal, and a value of the current I4 is changed, which leads to an increase in Vbe6.

At this time, as understood from the expression (1), Vbe4 and Vbe5 are changed oppositely from Vbe6. That is, if an amount of the sink current I4 of the transistor 106 as a current sinking transistor is small due to the input signal IN, the source current I3 of the transistor 108 as a current source transistor increases. In contrast, if an amount of I4 is large, an amount of I3 is reduced under the control. That is, unlike a conventional output circuit 3, such an idling current that is held constant does not flow the current source transistor. Incidentally, an operation of the class-AB output circuit 1 is described in detail below.

Next, an output voltage range of this embodiment is described. As shown in FIG. 1, in this embodiment, the collector terminal of the transistor 108 as the current source transistor is connected with the output terminal 114. Further, the emitter terminal of the transistor 108 is connected with a power supply Vcc. The collector terminal of the transistor 106 as the current sinking side transistor is connected with the output terminal 114. The emitter terminal of the transistor 106 as the current sinking side transistor is grounded (GND). That is, the collector terminals of the transistors 108 and 106 are connected with the output terminal 114, and the emitter terminals of the transistors 108 and 106 are connected with the power supply Vcc and the GND terminal, respectively. Hence, an output voltage can range from a GND level to a power supply level.

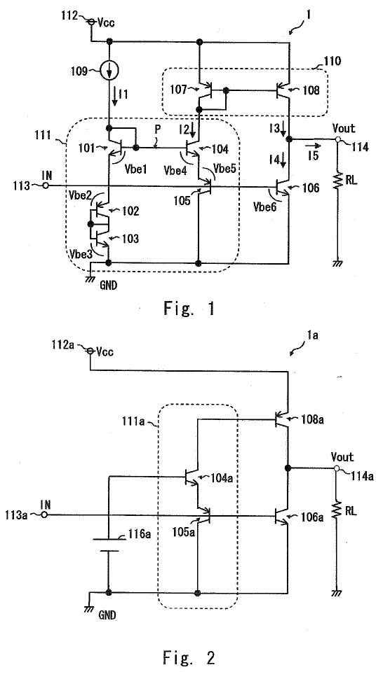

Referring to FIG. 2, an operation of the class-AB output circuit 1 of this embodiment is described in detail next. A circuit diagram of FIG. 2 simplifies the circuit configuration of FIG. 1 for explaining the operation of this embodiment. A class-AB output circuit 1a as the simplified circuit 1 includes two NPN transistors 104a and 106a, two PNP transistors 105a and 108a, and a battery 116a. In FIG. 2, the constant current circuit 109 of FIG. 1 is omitted. Further, diode-connected transistors 101 and 107 are simplified, and the transistors 102 and 103 are replaced by the battery 116a.

As shown in FIG. 2, an input terminal 113a is connected to a base terminal of the transistor 106a. An input signal IN applied to the input terminal 113a drives the transistor 106a. Further, the input terminal 113a is also connected to a base terminal of the transistor 105a. The input signal IN drives the transistor 105a as well. A collector terminal of the transistor 106a and a collector terminal of the transistor 108a are connected with an output terminal 114a. An emitter terminal of the transistor 106a is grounded. An emitter terminal of the transistor 108a is connected to a power supply 112a. A base terminal of the transistor 108a is connected to a collector terminal of the transistor 104a.

On the other hand, an emitter terminal of the transistor 105a is connected to an emitter terminal of the transistor 104a. A collector terminal of the transistor 105a is grounded (GND). The transistor 104a and the transistor 105a constitute an output control circuit 111a. Incidentally, a base terminal of the transistor 104a is grounded (GND) via the battery 116a.

If a base current of the transistor 106a increases due to the input signal IN, a base potential of the transistors 105a and 106a increases. Here, a base potential of the transistor 104a is fixed by the battery 116a. As the base potential of the transistors 105a and 106a increases, a difference between the potential and the base potential of the transistor 104a is decreased. Thus, a collector current of the transistor 104a reduces. As a result, a collector current of the transistor 108a reduces, and an output voltage Vout drops.

Further, if the base current of the transistor 106a decreases due to the input signal IN, the base potential of the transistors 105a and 106a is reduced. Here, the base potential of the transistor 104a is fixed by the battery 116a. As the base potential of the transistors 105a and 106a decreases, a difference between the potential and the base potential of the transistor 104a increases. Thus, the collector current of the transistor 104a increases. As a result, a collector current of the transistor 108a increases, and thus the output voltage Vout is raised.

As described above, an output of the transistor 108a is controlled by the output control circuit 111a, wherein input signal IN is applied to the transistor 105a, and the transistor 104a works corresponding to the transistor 105a. In other words, an output of the transistor 108a as the current source transistor is controlled based on a base voltage of the transistor 106a as the current sinking transistor.

Abase current of the transistor 108a as the current source transistor is a collector current of the transistor 104a and flows to the GND terminal through the transistor 105a. The input terminal 113a is connected to a base terminal of the transistor 105a. Hence, an input impedance can be increased by controlling the base current of the transistors 105a and 106a. That is, unlike the technique of Japanese Unexamined Patent Publication No. 2003-69346, it is unnecessary to supply a current using a constant current source or adopt an emitter follower circuit for the purpose of increasing an input impedance of a current sinking transistor.

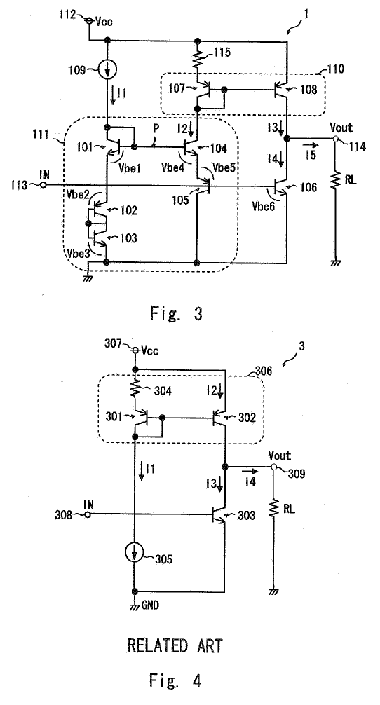

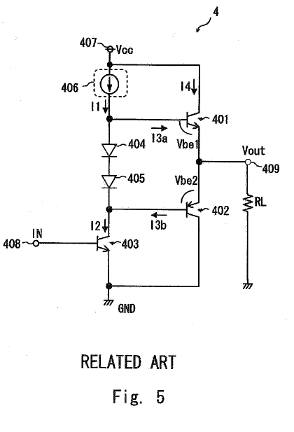

FIG. 3 shows another mode of this embodiment. In FIG. 3, a resistor 115 is inserted between the emitter terminal of the transistor 107 and the power supply Vcc of FIG. 1 to thereby constitute a Wydler constant current circuit 116. The other components are the same as those of FIG. 1, and thus description thereof is omitted here.

As shown in FIG. 3, the source current I3 can be increased by inserting the resistor 115. This is because the resistor 115 is connected to an emitter terminal of the transistor 108 as the current source transistor and an emitter terminal of the transistor 107 as the current mirror circuit to thereby generate the source current I3 amplified based on a resistance ratio with respect to the current I2 flowing the transistor 107.

As described above, in the class-AB output circuit 1 of this embodiment, an idling current varies depending on a load. Therefore, as compared with the conventional output circuit 3 where an idling current does not vary depending on a load, current consumption can be saved, and a power efficiency can be improved.

Further, the class-AB output circuit 1 of this embodiment can up the maximum value of the output voltage Vout to a power supply Vcc level and down the minimum value thereof a GND level. That is, the output voltage range can be expanded up to the power supply voltage level, making it possible to deal with reduction in operating voltage.

Further, in the class-AB output circuit 1 of this embodiment, the transistor 105 is positioned between base terminal of the transistor 104 and the transistor 106. Therefore, even if the base potential of the transistor 106 increases, a current flowing the transistor 104 is never entirely stopped. Thus, unlike the configuration of Japanese Patent Translation Publication No. 11-507773, it is unnecessary to supply a current for correcting an output impedance, so a power efficiency is improved.

Further, the class-AB output circuit 1 of this embodiment uses the transistor 105 to increase an input impedance with respect to the current sinking transistor. Thus, unlike the configuration of Japanese Unexamined Patent Publication No. 2003-69346, it is unnecessary to supply a current using the constant current source or insert the emitter follower circuit. As a result, current consumption of the circuit is reduced, and the power efficiency can be improved. Incidentally, an offset voltage of an input operation stage can be also increased by increasing the input impedance.

Further, in the class-AB output circuit 1 of this embodiment, if an input voltage of the input signal IN is lowered, control on a current of the transistor 108 as the current source transistor is not limited. That is, unlike the configuration of Japanese Unexamined Patent Publication No. 2003-69346, there is no fear that a constant current source for controlling an idling current limits an output voltage range. Hence, an output control can be executed with a wider range.

As another mode of the this embodiment, if a large amount of source current I3 is required in this embodiment, a current amount can be increased by increasing a channel area ratio between the transistors 107 and 108 constituting the current mirror circuit of FIG. 1 instead of inserting the resistor 115 as shown in FIG. 3.

It is apparent that the present invention is not limited to the above embodiment that may be modified and changed without departing from the scope and spirit of the invention.

What is claimed is:

1. An output circuit, comprising:
a first transistor connected between a high-potential-side power supply and an output terminal;
a second transistor connected between a low-potential-side power supply and the output terminal;
a third transistor constituting a current mirror circuit together with the first transistor;
a fourth transistor connected with the third transistor and controlling a drive current of the first transistor; and
a fifth transistor supplying a current corresponding to a base potential of the second transistor to the fourth transistor.

2. The output circuit according to claim 1, wherein a base terminal of the second transistor and a base terminal of the fifth transistor are connected to a common input terminal.

3. The output circuit according to claim 2, wherein an emitter terminal of the fifth transistor is connected with a base terminal of the first transistor via the fourth transistor.

4. The output circuit according to claim 1, further comprising a sixth transistor constituting a current mirror circuit together with the fourth transistor.

5. The output circuit according to claim 4, wherein the sixth transistor is connected with GND via a diode-connected transistor to generate a reference voltage.

6. The output circuit according to claim 1, wherein a resistor is connected between an emitter terminal of the third transistor and a high-potential-side power supply.

7. The output circuit according to claim 1, wherein an emitter terminal of the first transistor is connected to a high-potential-side power supply,
a collector terminal of the first transistor is connected to an output terminal,
an emitter terminal of the second transistor is connected to a low-potential-side power supply, and
a collector terminal of the second transistor is connected to the output terminal.

8. An output circuit, comprising:
a first transistor having a first terminal connected to a high-potential-side power supply and having a second terminal connected to an output terminal;
a second transistor having a first terminal connected to a low-potential-side power supply and having a second terminal connected to the output terminal and having a base terminal connected to an input terminal;
a fourth transistor having a second terminal connected to a base terminal of the first transistor; and
a fifth transistor having a first terminal connected to a first terminal of the fourth transistor and having a base terminal connected to the input terminal.

9. The output circuit according to claim 8, wherein the base terminal of the second transistor and the base terminal of the fifth transistor are connected with a common input terminal.

10. The output circuit according to claim 9, wherein the second terminal of the first transistor and the second terminal of the second transistor are connected mutually, and an output voltage is output from a node between the first transistor and the second transistor.

11. The output circuit according to claim 8, further comprising a third transistor having a first terminal connected to the high-potential-side power supply and having a second terminal connected to the second terminal of the fourth transistor and having a base terminal connected to the base terminal of the first transistor, and the base terminal of the third transistor and the second terminal of the third transistor is connected mutually.

12. The output circuit according to claim 8, wherein a constant voltage is supplied to a base terminal of the fourth transistor.

13. The output circuit according to claim 8, wherein the first terminal is one of an emitter terminal or a collector terminal, and the second terminal is the other one of a emitter terminal or a collector terminal.
